(19) United States
(12) Patent Application Publication
(10) Pub. No.: US 2013/0188318 A1
(43) Pub. Date: Jul. 25, 2013

(54) HEAT DISSIPATION STRUCTURE AND ELECTRONIC DEVICE WITH THE SAME

(71) Applicant: LITE-ON TECHNOLOGY CORPORATION, Taipei (TW)

(72) Inventors: Ya-Tung I, New Taipei City (TW); Yi-Jen LU, Jiaoxi Township (TW)

(73) Assignee: LITE-ON TECHNOLOGY CORPORATION, Taipei (TW)

(21) Appl. No.: 13/646,302

(22) Filed: Oct. 5, 2012

(30) Foreign Application Priority Data
Jan. 20, 2012 (TW) 101102615

(51) Int. Cl. H05K 7/20; F28F 7/00

(52) U.S. Cl. 361/713; 165/185

(57) ABSTRACT

An electronic device includes a circuit board, a plurality of electronic components, a heat dissipation structure and a casing. The electronic components are disposed on the circuit board. The heat dissipation structure includes a first electrically insulating and thermally conductive layer and a metal layer. The first electrically insulating and thermally conductive layer covers the circuit board and/or the electronic components. The thermal conductivity coefficient of the first electrically insulating and thermally conductive layer is greater than 0.5 W/m.k. The metal layer is combined and thermal contacted with the first electrically insulating and thermally conductive layer. The casing has an accommodating space. The circuit board, the electronic components and the heat dissipation structure are received in the accommodating space, and the metal layer is disposed between the casing and the first electrically insulating and thermally conductive layer.

### CROSS-REFERENCE TO RELATED APPLICATIONS

This non-provisional application claims priority under 35 U.S.C. §119(a) on Patent Application No(s). 101102615 filed in Taiwan, R.O.C. on Jan. 20, 2012, the entire contents of which are hereby incorporated by reference.

### BACKGROUND

1. Technical Field

The disclosure relates to a heat dissipation structure and more particularly to a heat dissipation structure for evening the temperature distribution on a surface of an electronic device and quickly reducing the high temperature of electronic components in the electronic device, and an electronic device having such a heat dissipation structure.

2. Related Art

Adapters and power supply devices are essential electronic devices for the operation of various electrical appliances and equipments. Such electronic devices may have many electronic components disposed on the circuit board therein. These electronic components not only include components of high power consumption such as transformers, metal-oxide-semiconductor field effect transistors (MOSFET), diodes and inductors, but also include components of low power consumption such as capacitors and resistors. When the electronic device is at work and if the heat generated by the electronic components therein cannot be dissipated effectively, the heat will be accumulated in the electronic device and causes the temperature of the electronic components to rise. Once the temperature of the electronic components gets too high, the electronic components may be abnormal or even burnt out.

Taking an adapter for illustration, it is used to convert an external voltage into the voltage required by an electronic appliance such as a portable computer. However, the size of the adapter becomes smaller as electronic components therein are being integrated, and thus the heat dissipation has become a more serious problem because of the compact size of the adapter.

For example, the casing of a conventional adapter is made of plastic. Because the material of plastic is unfavorable for heat dissipation, when the heat generated by the electronic components on the circuit board is transferred to the casing, the temperature on the regions of the casing corresponding to the components of high power consumption is usually higher than the temperatures on other regions of the casing. The high temperature at a specific region of the casing may cause a user to feel uncomfortable or even get burnt. Furthermore, the heat dissipation efficiency of the casing will be reduced because the heat is concentrated at the specific region of the casing.

Furthermore, due to the trend that an electronic device becomes more compact, the space inside the electronic device is very small. Deducting the space required for electronic components inside the electronic device, the remaining space available for a heat dissipation structure is limited. Therefore, it is more difficult to design the heat dissipation structure in such a limited space.

Based on the above, to design a heat dissipation structure without occupying too much interior space of the electronic device in order to even the temperature distribution of the surface of an electronic device and to quickly reduce the high temperature of electronic components therein is an issue urgently needed to be solved.

### SUMMARY

In one aspect, an electronic device comprises a circuit board, a plurality of electronic components electrically connected to the circuit board, a heat dissipation structure and a casing. The casing comprises a first electrically insulating and thermally conductive layer and a metal layer. The first electrically insulating and thermally conductive layer covers the circuit board and/or the plurality of electronic components and has a thermal conductivity coefficient of greater than 0.5 W/m.k. The metal layer combines with and is in thermal contact with the first electrically insulating and thermally conductive layer. The casing has an accommodating space in which the circuit board, the plurality of electronic components and the heat dissipation structure are accommodated. The metal layer is disposed between the casing and the first electrically insulating and thermally conductive layer.

In another aspect, a heat dissipation structure comprises a first electrically insulating and thermally conductive layer and a metal layer. The first electrically insulating and thermally conductive layer has a thermal conductivity coefficient of greater than 0.5W/m.k. The metal layer is in thermal contact and chemically bonded with the first electrically insulating and thermally conductive layer

### BRIEF DESCRIPTION OF THE DRAWINGS

The present disclosure will become more fully understood from the detailed description given herein below for illustration only, and thus are not limitative of the present disclosure, and wherein:

FIG. 1 is a perspective view of an electronic device according to a first embodiment of the disclosure;

FIG. 2 is an exploded view of the electronic device in FIG. 1;

FIG. 3 is a cross-sectional view of the electronic device in FIG. 1 along the line 3-3;

FIG. 4 is a graph showing temperatures of hot spots of a casing of the electronic device with a conventional heat dissipation structure and a casing of the electronic device of the embodiment;

FIG. 5 is a graph showing temperatures of electronic components in the electronic device with the conventional heat dissipation structure and electronic components in the electronic device of this embodiment;

FIG. 6 is a cross-sectional view of an electronic device which is derived from the first embodiment of the disclosure;

FIG. 7 is a cross-sectional view of an electronic device according to a second embodiment of the disclosure;

FIG. 8 is an exploded view of the electronic device which is derived from the first embodiment;

FIG. 9 is a cross-sectional view of the electronic device in FIG. 8;

FIG. 10 is a cross-sectional view of an electronic device according to a third embodiment of the disclosure;

FIG. 11 is a cross-sectional view of an electronic device according to a fourth embodiment of the disclosure;

FIG. 12 is a cross-sectional view of an electronic device derived from the first embodiment of the disclosure;

FIG. 13 is a cross-sectional view of an electronic device according to a fifth embodiment of the disclosure; and

FIG. 14 is a cross-sectional view of an electronic device according to a sixth embodiment of the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

The term “thermal contact” described herein is referred to the combination way between two objects, and in this combination way the heat can be transferred from one object to another object through thermal conduction.

The term “cover” described herein is referred to that a covering object surrounds completely or partially a to-be-covered object and the covering object may contact or may not contact the to-be-covered object.

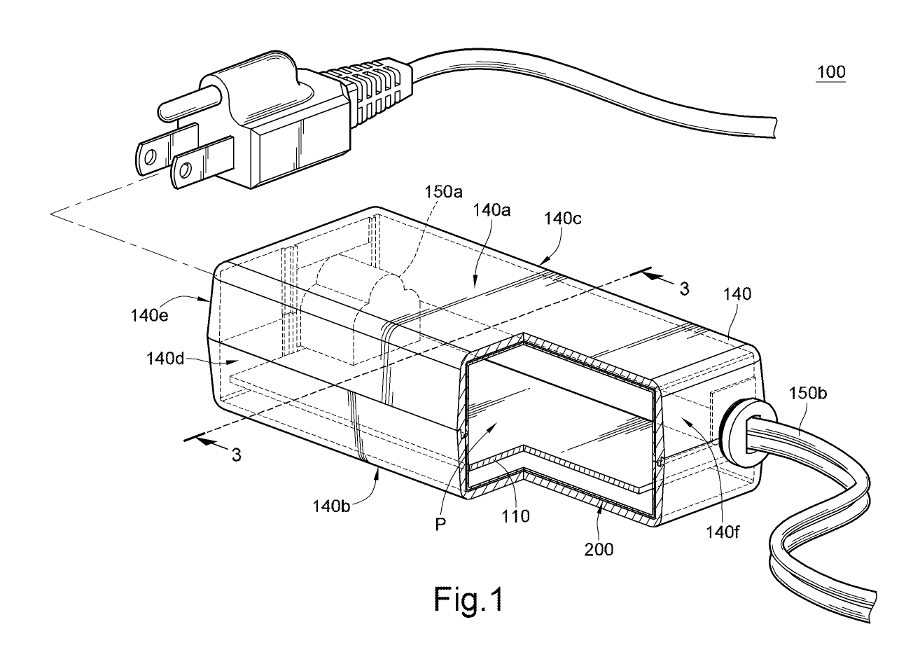

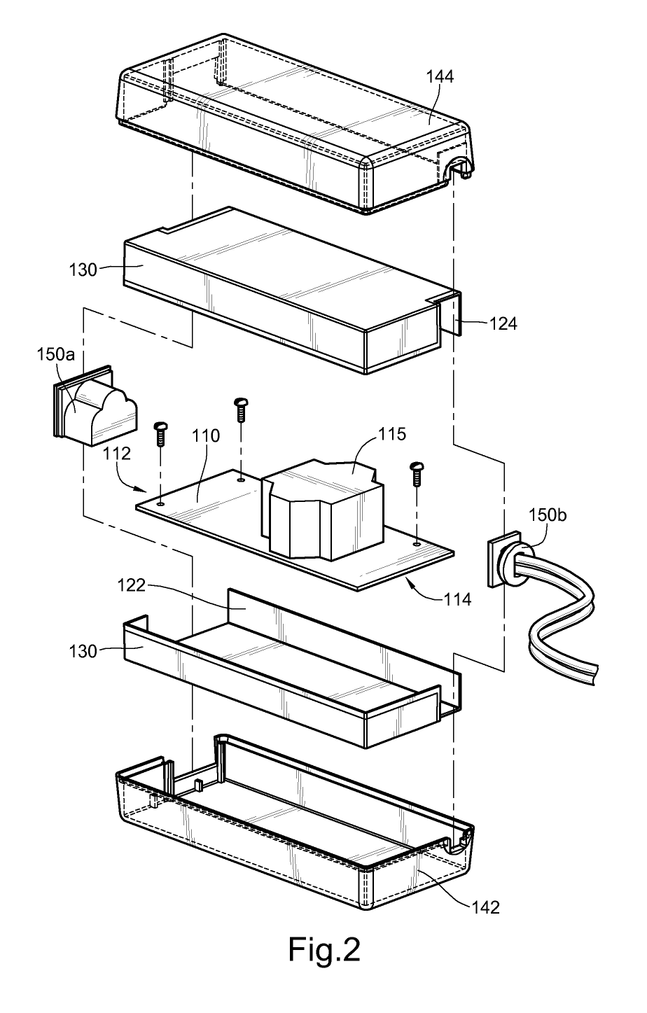

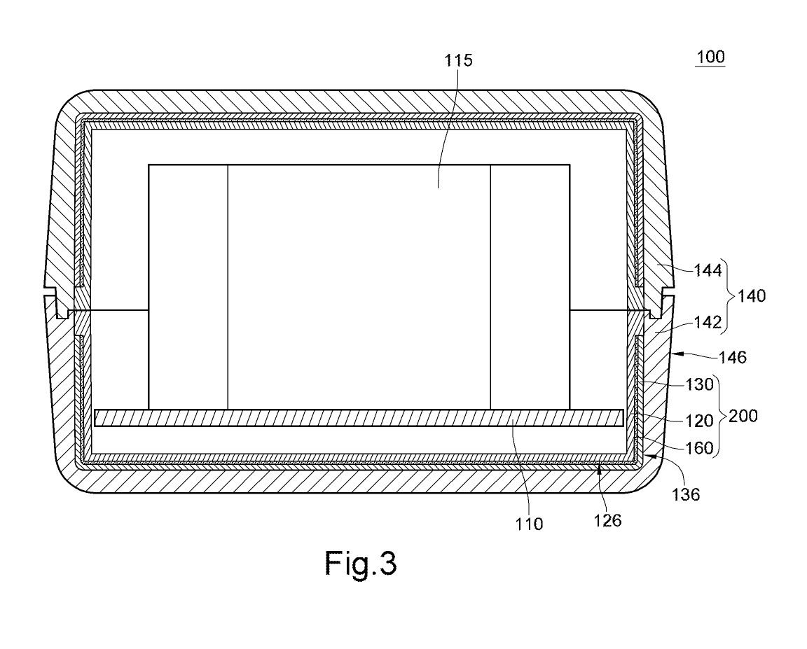

FIG. 1 is a perspective view of an electronic device according to a first embodiment of the disclosure. FIG. 2 is an exploded view of the electronic device in FIG. 1. FIG. 3 is a cross-sectional view of the electronic device taken along the line 3-3 of FIG. 1. Referring to FIGS. 1-3, for easy explanation, the electronic device 100 of the first embodiment is exemplified as an adapter, but is not limited as such. In other embodiments, the electronic device 100 can also be a power supply or other types of electronic products such as a Universal Serial Bus (USB) digital television tuner. The electronic device 100 comprises a circuit board 110, a plurality of electronic components 115 (only one electronic component shown for concise illustration), a heat dissipation structure 200, and a casing 140. The heat dissipation structure 200 comprises a first electrically insulating and thermally conductive layer 120 and a metal layer 130, and the first electrically insulating and thermally conductive layer 120 and the metal layer 130 are appropriately treated to be combined to form the heat dissipation structure 200.

The electronic components 115 are disposed on and electrically connected to the circuit board 110. The electronic components 115 can be disposed on or under the circuit board 110. The electronic components 115 can be, for example, metal-oxide-semiconductor field effect transistor (MOSFET), diode, inductor, capacitor, resistor, or other electronic components. In this embodiment and some embodiments of the disclosure, the power input element 150a and the power output element 150b can be respectively one of a plug, a socket and a power cord. For easy explanation, in the following embodiments, the power input element 150a is exemplified as a socket (which can be externally connected to a power plug for inputting mains electricity), and the power output element 150b is exemplified as a power cord through which the electronic device, i.e. the adapter, is electrically connected to an electronic device such as a portable computer. Furthermore, based on the positions of the power input element 150a and the power output element 150b, the circuit board 110 is divided into a voltage input side 112 (or a primary side) and a voltage output side 114 (or a secondary side). The voltage input side 112 is referred to one side of the circuit board 110 which is electrically connected to the power input element 150a, and the voltage output side 114 is referred to the other side of the circuit board 110 which is electrically connected to the power output element 150b.

The first electrically insulating and thermally conductive layer 120 of the heat dissipation structure 200 covers the circuit board 110 or the electronic components 115. In this embodiment and some other embodiments, the first electrically insulating and thermally conductive layer 120 comprises a first portion 122 and a second portion 124. The first portion 122 and the second portion 124 together cover the circuit board 110 and the electronic components 115 on the circuit board 110. More specifically, the first portion 122 and the second portion 124 together form a hexahedral structure. Both ends of the hexahedral structure have a respective opening to merely expose the power input element 150a and the power output element 150b respectively. In other words, the first electrically insulating and thermally conductive layer 120 constructed of the first portion 122 and the second portion 124 shelters portions of the voltage input side 112 and portions of the voltage output side 114. However, according to the definition of the term “cover” mentioned above, this embodiment is not intended to limit the way that the first electrically insulating and thermally conductive layer 120 covers the circuit board 110 and the electronic components 115. In still some other embodiments, the first electrically insulating and thermally conductive layer 120 may merely cover a part of the circuit board 110, or cover a part of the electronic components 115, or cover a part of the circuit board 110 and a part of the electronic components 115. In addition, in some other embodiments, the first insulating and heat conduction layer 120 may wholly cover the circuit board 110 and/or the electronic components 115.

The thermal conductivity coefficient of the first electrically insulating and thermally conductive layer 120 is larger than 0.5 W/m·k, and the first electrically insulating and thermally conductive layer 120 is preferably a soft material. In this embodiment, the first electrically insulating and thermally conductive layer 120 can be made of, for example, heat conductive silicone, heat conductive rubber, or other suitable materials. Furthermore, the term “electrically insulating” is referred to a characteristic of an object. In this embodiment, the electronic device 100 is exemplified as an adapter. In this art, when the object such as the first electrically insulating and thermally conductive layer 120 or the electronic device 100 undergoes a Hi-Pot test by being inputted with a direct voltage of 4242 volts or an alternating voltage of 3000 volts for a specified time period, the object is regarded to be electrically insulative provided that no insulation breakdown occurs during the test. It should be noted that the term “electrically insulating” may have different definitions when this invention is applied in different technical fields.

The metal layer 130 thermally contacts with the first electrically insulating and thermally conductive layer 120. The metal layer 130 is disposed between the first electrically insulating and thermally conductive layer 120 and the casing 140. The area and disposition of the metal layer 130 combined to the first electrically insulating and thermally conductive layer 120 can be appropriately adjusted according to the heat dissipation or safety requirements of the electronic device 100. In other words, the covering area of the first electrically insulating and thermally conductive layer 120 and that of the metal layer 130 are not necessarily the same. As shown in FIGS. 1 and 3, the surrounding of the metal layer 130 is indented by a certain distance comparing with that of the first electrically insulating and thermally conductive layer 120 due to the safety requirement on the adapter. Alternatively, the metal layer 130 may be applied merely in partial regions.

The metal layer 130 can be made of aluminum, iron, copper or other metal. In manufacture, one embodiment is that the metal layer 130 can be shaped according to the requirements of heat dissipation or the shape of the casing etc. Then, the metal layer 130 is put in a mold, and the first electrically insulating and thermally conductive layer 120 can be combined with the metal layer 130 to form the heat dissipation structure 200 based on the shape of the metal layer 130 or the shape that first electrically insulating and thermally conductive layer 120 is to cover.

In this embodiment and some other embodiments, the first electrically insulating and thermally conductive layer 120 is combined with the metal layer 130 through chemical treatment, preferably chemical bonding, to form a one-piece heat dissipation structure 200, which can be used as a separate component. More particularly, the heat dissipation structure 200 further comprises a first adhesion 160 with which the first electrically insulating and thermally conductive layer 120 is coated, for instance, to combine with the metal layer 130. The first adhesion 160 is respectively chemically bonded with the first electrically insulating and thermally conductive layer 120 and with the metal layer 130. The chemical bonding may be, for example, cross-linking or vulcanization. The first adhesion 160 may be a coupling agent such as silane coupling agent or titanate coupling agent, etc. For example, the first electrically insulating and thermally conductive layer 120 is a heat conductive silicone, the metal layer 130 is aluminum, and the first adhesion 160 is a silane coupling agent.

The casing 140 has an accommodating space P. In this embodiment, the casing 140 comprises a first casing 142 and a second casing 144. The circuit board 110 is disposed in the first casing 142. The second casing 144 is covered onto the first casing 142 so as to hold the circuit board 110, the electronic components 115, and the heat dissipation structure 200 in the accommodating space P constructed by the first casing 142 and the second casing 144.

The circuit board 110 and the electronic components 115 are covered by the heat dissipation structure 200. The casing 140 comprises an upper surface 140a, a bottom surface 140b, a right surface 140c, a left surface 140d, an electric power input side surface 140e, and an electric power output side surface 140f. The electric power input side surface 140e and the electric power output side surface 140f are opposite to each other. The upper surface 140a, the bottom surface 140b, the right surface 140c, the left surface 140d, the electric power input side surface 140e, and the electric power output side surface 140f are connected to form the accommodating space P. The first electrically insulating and thermally conductive layer 120 is disposed near to the inner surfaces of the casing 140 opposite to the upper surface 140a, the bottom surface 140b, the right surface 140c, the left surface 140d, the electric power input side surface 140e, and the electric power output side surface 140f, to form a hexahedral structure. In addition, the first electrically insulating and thermally conductive layer 120 covers or shields parts of both the voltage input side 112 and the voltage output side 114. In this embodiment, the casing 140 can be made of such as plastic, but it may be made of other materials suitable for other electronic devices. Furthermore, the heat dissipation structure 200 and the casing 140 can be assembled together through being tightly fitted with each other. As a result, assembly of the heat dissipation structure 200 into the electronic device 100 can be accomplished simply by putting the heat dissipation structure 200 into the casing 140 to abut against the inner surfaces thereof. Therefore, the assembling efficiency of the electronic device 100 can be enhanced by closely fitting the heat dissipation structure 200 to the casing 140, and the manufacturing time for the electronic device 100 can be reduced.

The first electrically insulating and thermally conductive layer 120 of the heat dissipation structure 200 may contact or not contact the circuit board 110 and/or the electronic components 115.

The heat dissipation mechanism of the electronic device 100 will be described in details below.

When the electronic device 100 is in operation, the heat generated by the circuit board 110 or the electronic components 115 can be transferred to the first electrically insulating and thermally conductive layer 120 by thermal convection or thermal conduction. Then, when the heat is transferred to the metal layer 130 from the first electrically insulating and thermally conductive layer 120, the heat will spread over the first electrically insulating and thermally conductive layer 120 and the metal layer 130 so that the temperature of each part of the heat dissipation structure 200 will trend toward uniform.

Since the thermal conductivity coefficient of the metal layer 130 is larger than that of the first electrically insulating and thermally conductive layer 120, the heat spreading speed in the metal layer 130 is larger than that in the first electrically insulating and thermally conductive layer 120. Therefore, the temperature distribution of each part of the surface 136 of the metal layer 130 is much more uniform than that of the surface 126 of the first electrically insulating and thermally conductive layer 120.

Afterwards, the heat is transferred to the casing 140 from the metal layer 130 and then is dissipated from the outer surface 146 of the casing 140 to the external environment.

In the process that the heat generated by the circuit board 110 and the electronic components 115 is transferred to the casing 140, because the heat spreads uniformly over the first electrically insulating and thermally conductive layer 120 and the metal layer 130 before it is transferred to the casing 140, the temperature distribution on each part of the outer surface 146 of the casing 140 of this embodiment is more uniform comparing with the use of a conventional heat dissipation structure (i.e., a metal heat dissipation sheet and an insulation sheet disposed in a casing). Therefore, the temperatures of hot spots generated on the outer surface 146 of the casing 140 can be greatly reduced by the heat dissipation structure 200 of this embodiment so that the electronic device 100 of this embodiment has better heat dissipation efficiency.

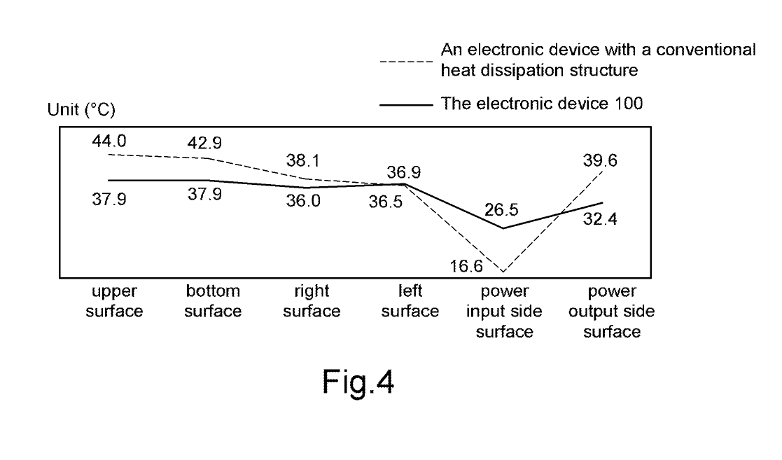

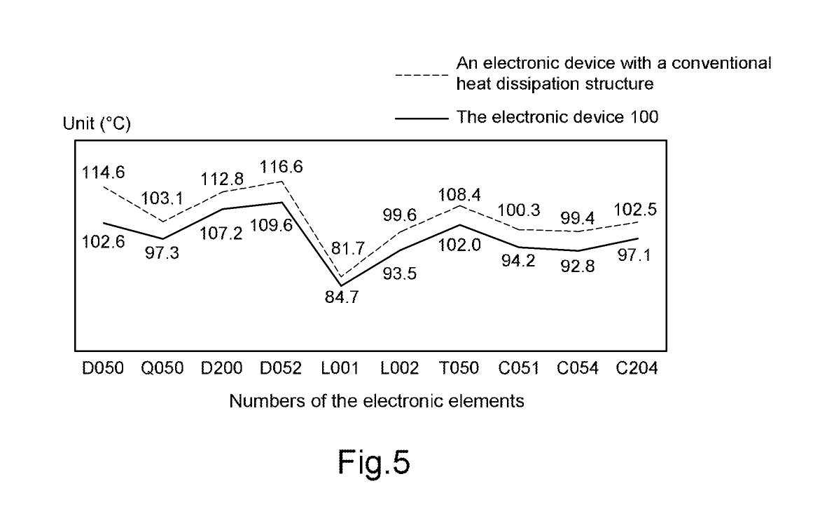

FIG. 4 is a graph showing temperatures of hot spots of the casing of an electronic device with a conventional heat dissipation structure and those of the electronic device 100 according to this embodiment. The temperature of a hot spot shown in FIG. 4 represents a relative temperature difference between the hot spot and the environment. FIG. 5 is a graph showing temperatures of the respective electronic components in the electronic device with the conventional heat dissipation structure and those of the electronic device 100 of this embodiment. In the embodiment of FIGS. 4 and 5, the thickness of the metal layer 130 is 0.3 mm and the thickness of the first electrically insulating and thermally conductive layer 120 is 0.45 mm. As shown in FIG. 4, the temperature of the hottest spot of the casing of the electronic device using the conventional heat dissipation structure is 44 degrees Celsius, while the temperature of the hottest spot (on the upper surface 140a) of the casing 140 of the electronic device 100 of this embodiment is only 37.9 degrees Celsius. That is, the latter is 6.1 degrees Cesius lower in temperature than the former. Furthermore, the temperature of the hot spot on the bottom surface 140b of the casing 140 of the electronic device 100 is 5 degrees Celsius lower than that of the casing of the conventional electronic device. Since the upper and bottom surfaces are both often touched by users, the temperature reduction of the hot spots of the upper and bottom surfaces is very important. In addition, even if additional metal plates (at least 0.5 mm of thickness) are stacked in multi-layers or an additional copper aluminum foil (less than 0.5 mm of thickness) is attached to the inner surfaces of the casing to assist the conventional heat dissipation structure in reducing the temperature of the casing, the temperature of the casing can only be reduced at most about 3 degrees Celsius in this way and this way incurs additional costs. Accordingly, the heat dissipation structure in the electronic device 100 of this embodiment can reduce the temperatures of the hot spots on the casing much more effectively and economically.

Furthermore, the entire thickness of the heat dissipation structure 200 assembled into the electric device 100 is thinner than that of the conventional heat dissipation structure, and therefore, the electronic device 100 with the use of the heat dissipation structure 200 will have a bigger accommodating space under the condition that the electronic device is regulated with a fixed size specification,

As shown in FIG. 5, the temperatures of the respective electronic components in the electronic device 100 are lower than those of the electronic components in the electronic device using the conventional heat dissipation structure. As for the hottest electronic component (No. D052), its temperature is reduced as much as 7 degrees Celsius when the heat dissipation structure 200 is used. The temperature of the second hottest electronic component (No. D050) is reduced as much as 12 degrees Celsius when the heat dissipation structure 200 is used. It can be seen that the temperatures of the electronic components in the electronic device 100 can be reduced more effectively compared with the conventional electronic device.

Furthermore, if the first electrically insulating and thermally conductive layer 120 of the heat dissipation structure 200 is made of soft materials such as heat conductive silicone or heat conductive rubber, a specific shape of the heat dissipation structure 200 can be maintained because the metal layer 130 can provide the required rigidity. For this end, manufactures may firstly manufacture and reserve such a one-piece heat dissipation structures 200 before assembling the electronic device 100. When assembling the electronic device 100, the single-piece heat dissipation structure 200 can be used as a component to be placed in the casing 140 either by man or mechanical equipment. Therefore, the working procedures, the assembling hours, and the number of operators can be effectively reduced (approximately 10%) by using the heat dissipation structure 200 of this embodiment.

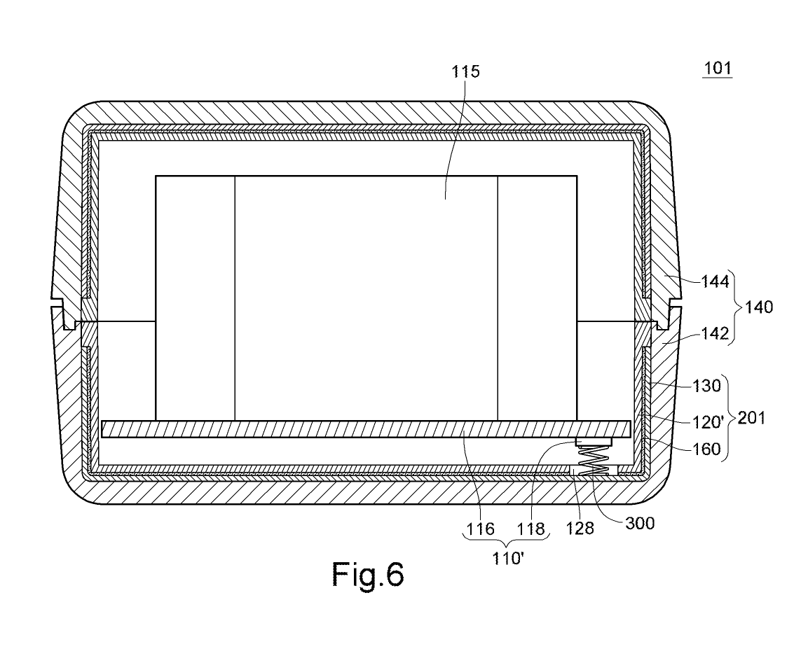

FIG. 6 is a cross-sectional view of an electronic device which is derived from the first embodiment of the disclosure. In FIG. 6, element with the same reference sign represents the same or similar element. The electronic device 101 of this embodiment differs from the electronic device 100 of the embodiment in FIG. 1 in that, the metal layer 130 of the heat dissipation structure 201 is electrically connected to the circuit board 110′ and the circuit board 110′ is connected to the ground. As a result, the electromagnetic interference (EMI) of the electronic components can be prevented. More specifically, the first electrically insulating and thermally conductive layer 120′ has an opening 128 and a part of the metal layer 130 of the heat dissipation structure 201 is exposed by the opening 128. The circuit board 110′ comprises a main body 116 and a ground connection portion 118. The main body 116 comprises a ground layer which is electrically connected to the ground connection portion 118. The ground connection portion 118 is electrically connected to the exposed part of the metal layer 130 by such an elastic electric conductive element 300.

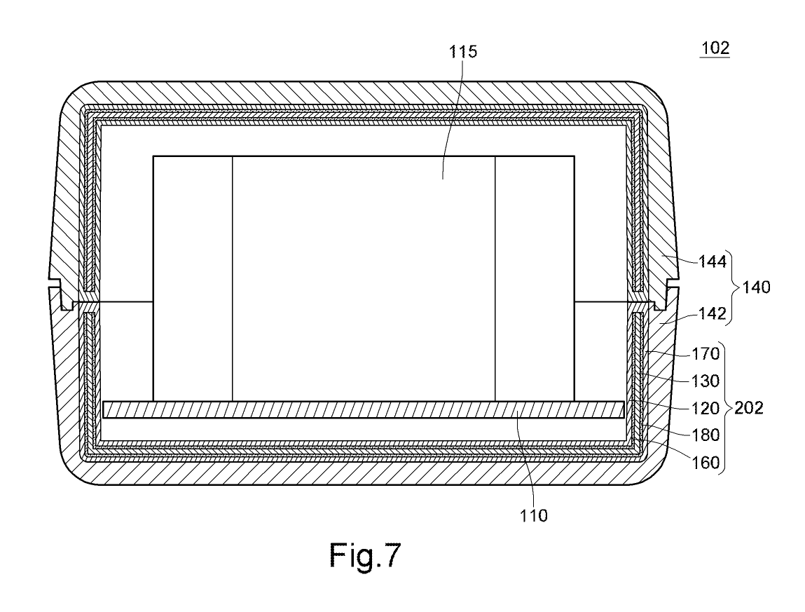

FIG. 7 is a cross-sectional view of an electronic device according to a second embodiment of the disclosure. In FIG. 7, element with the same reference sign represents the same or similar element. The electronic device 102 of this embodiment differs from the electronic device 100 of the embodiment in FIG. 1 in that, the heat dissipation structure 202 further comprises a second electrically insulating and thermally conductive layer 170 in addition to the first electrically insulating and thermally conductive layer 120 and the metal layer 130. Preferably, the second electrically insulating and thermally conductive layer 170 and the first electric insulting and heat conduction layer 120 cover the metal layer 130 together so as to avoid violating safety regulations. In other words, the metal layer 130 is disposed between the first electrically insulating and thermally conductive layer 120 and the second electrically insulating and thermally conductive layer 170. The second electrically insulating and thermally conductive layer 170 has a thermal conductivity coefficient of greater than 0.5 W/m.k and can be made of, for example, heat conductive rubber or heat conductive silicone. Because the second electrically insulating and thermally conductive layer 170 of this embodiment is made of soft material and thus has plasticity, the second electrically insulating and thermally conductive layer 170 can be in better contact with the casing 140 compared with the metal layer 130 of the embodiment in FIG. 1. Therefore, in this embodiment, the heat generated by the electronic components 115 can be transferred to the surface of casing 140 more quickly such that the temperatures of the electronic components 115 can be reduced more quickly. In other words, the heat dissipation structure 202 of this embodiment can speedily transfer the heat generated by those electronic components 115 of high temperature inside the electronic device 100 to the surface of the case 140 so as to reduce their temperatures.

Preferably, the second electrically insulating and thermally conductive layer 170 is combined with the metal layer 130 by chemical bonding, and the metal layer 130 is covered entirely together by the second electrically insulating and thermally conductive layer 170 and the first electrically insulating and thermally conductive layer 120 to form the one-piece heat dissipation structure 202. Regarding the chemical bonding, the heat dissipation structure 202 comprises a second adhesion layer 180, and the second electrically insulating and thermally conductive layer 170 is in thermal contact with the metal layer 130 through the second adhesion 180. The way of chemical bonding of the second adhesion 180 between the second electrically insulating and thermally conductive layer 170 and the metal layer 130 is similar to the way of chemical bonding of the first adhesion 160 between the first electrically insulating and thermally conductive layer 120 and the metal layer 130 in the first embodiment, and thus it will be not reiterated.

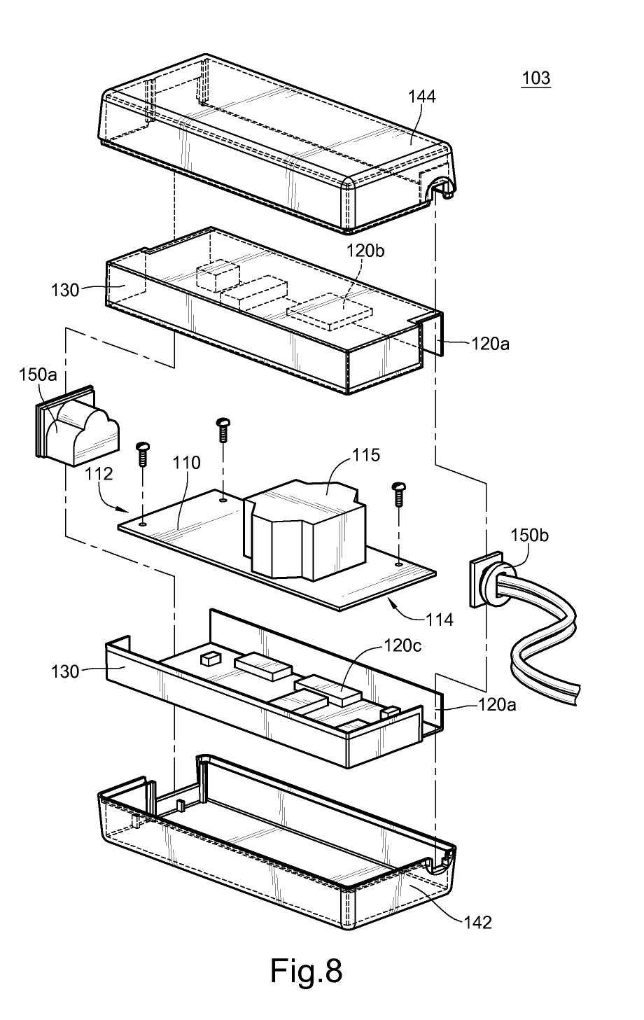

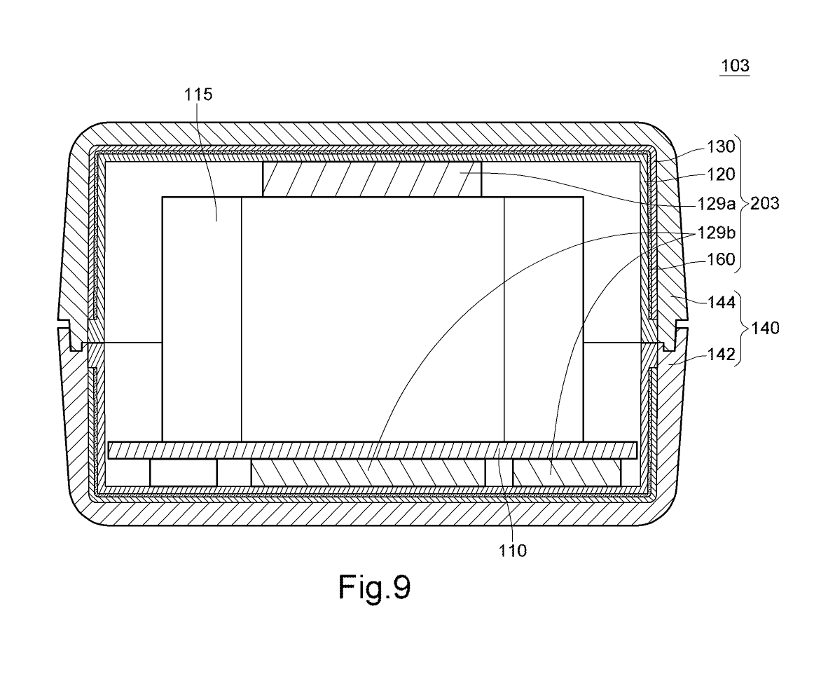

FIG. 8 is an exploded view of an electronic device of another variation which is derived from the first embodiment. FIG. 9 is a cross-sectional view of the electronic device in FIG. 8. With reference to FIGS. 8 and 9, element with the same reference sign represents the same or similar element. The heat dissipation structure 203 of the electronic device 103 further comprises a bump 129a. The bump 129a is extended toward the accommodating space P from the first electrically insulating and thermally conductive layer 120 and is in thermal contact with at least one of the electronic components 115. The thermal conductivity coefficient of the bump 129a is greater than 0.5 W/m.k. Therefore, the heat generated by the electronic component 115 can be transferred to the bump 129a by heat conduction, and the heat is then transferred to the first electrically insulating and thermally conductive layer 120 from the bump 129a. As a result, the heat generated by the electronic component 115 of the electronic device 103 can be transferred more quickly to the first electrically insulating and thermally conductive layer 120 compared with the embodiment in FIG. 1. Furthermore, the bump 129a can be made of a material that is the same as or different from that of the first electrically insulating and thermally conductive layer 120. Preferably, the bump 129a is formed together with the first electrically insulating and thermally conductive layer 120 as a whole. Alternatively, the bump 129a can be assembled on the first electrically insulating and thermally conductive layer 120.

In this embodiment, the heat dissipation structure 203 may further comprise a bump 129b in addition to the bump 129a. The bump 129b is extended to the accommodating space P from the first electrically insulating and thermally conductive layer 120 and is in thermal contact with the circuit board 110. The thermal conductivity coefficient, the way of connection with the circuit board 110, and the functions of the bump 129b are similar to those of the bump 129a, and thus they will not be reiterated. Furthermore, the bump 129b can also be used as a supporter for supporting or positioning the circuit board 110. The bump 129b can be made of non heat-conductive material. The bump 129b can be formed together with the first electrically insulating and thermally conductive layer 120 as a whole. The positions of the bump 129a and the bump 129b can be determined according to heat dissipation requirements of the electronic device 100.

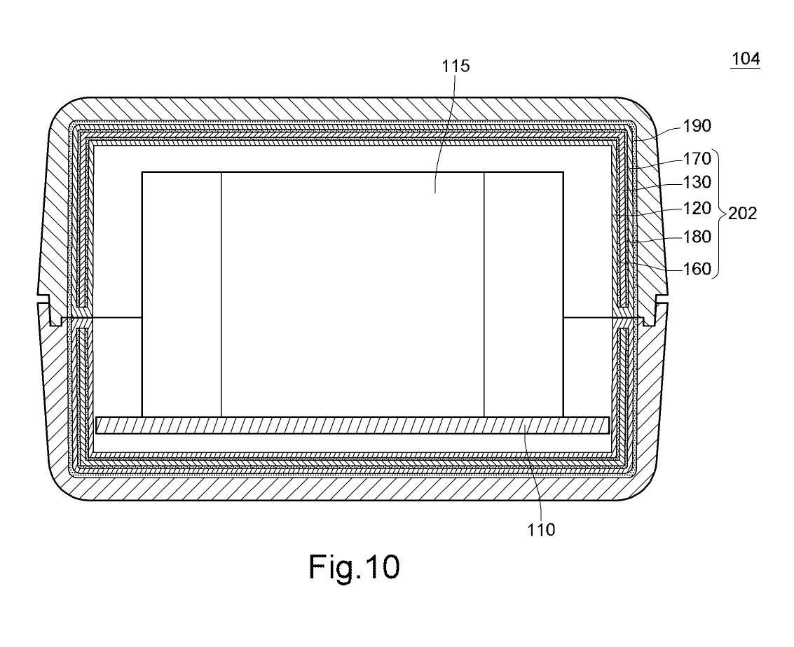

FIG. 10 is a cross-sectional view of an electronic device according to a third embodiment of the disclosure. With reference to FIG. 10, element with the same reference sign represents the same or similar element. This embodiment differs from the embodiment in FIG. 7 in that, in this embodiment, the second electrically insulating and thermally conductive layer 170 is combined with the casing 140 through a third adhesion 190, which is chemically bonded respectively with the second electrically insulating and thermally conductive layer 170 and the casing 140. The way of chemical bonding in this embodiment is similar to the way of chemical bonding of the first adhesion layer 160 respectively with the first electrically insulating and thermally conductive layer 120 and the metal layer 130 in the first embodiment, and thus it will not be reiterated.

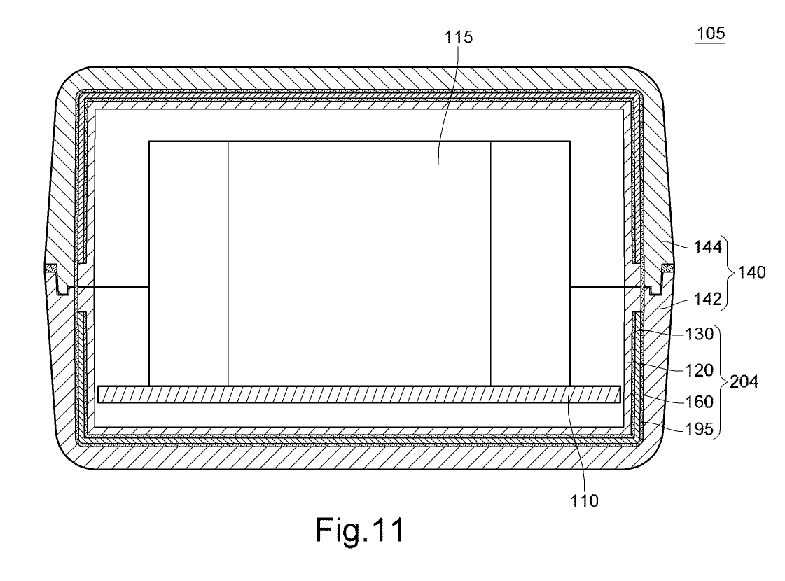

FIG. 11 is a cross-sectional view of an electronic device according to a fourth embodiment of the disclosure. With reference to FIG. 11, element with the same reference sign represents the same or similar element. This embodiment differs from the embodiment in FIG. 3 in that, in this embodiment, the heat dissipation structure 204 further comprises a fourth adhesion 195, and the metal layer 130 is combined with the casing 140 through the fourth adhesion 195. The fourth adhesion 195 is chemically bonded respectively with the metal layer 130 and the casing 140. The way of chemical bonding is similar to the way of chemical bonding of the first adhesion 160 respectively with the first electrically insulating and thermally conductive layer 120 and the metal layer 130 in the first embodiment, and thus it will not be reiterated.

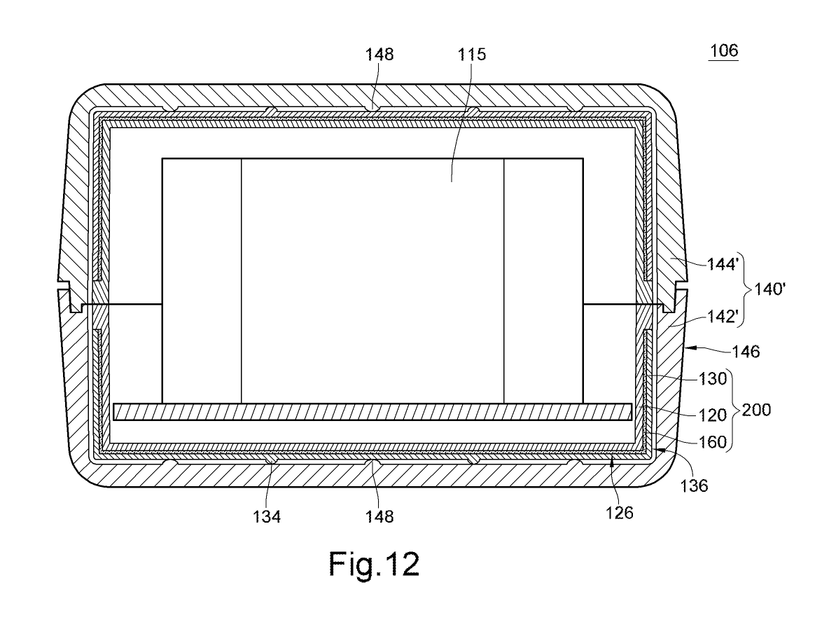

FIG. 12 is a cross-sectional view of an electronic device of still another variation which is derived from the first embodiment of the disclosure. With reference to FIG. 12, element with the same reference sign represents the same or similar element. The electronic device 106 of this embodiment differs from the embodiment in FIG. 3 in that, the casing 140′ further comprises at least one protrusion 148 disposed on a second casing 144′ and a first casing 142′. Preferably, the protrusions 148 can be formed on the inner side of the casing 140′ by injection molding so that the heat dissipation structure 200 is in partial contact with the casing 140′. More specifically, in this embodiment, the protrusions 148 are extended toward the accommodating space P and are in contact with the metal layer 130 of the heat dissipation structure 200 such that a gap is formed between the heat dissipation structure 200 and the casing 140′. The thermal resistance between the heat dissipation structure 200 and the casing 140′ is increased by the gap such that the heat transferred from the heat dissipation structure 200 directly to the surface of the casing 140′ can be slowed down so as to make the heat transfer and spread more uniformly in the heat dissipation structure 200 and to further reduce the temperatures of the hot spots on the surface of the casing 140′. In the other hand, at least one protrusion 134 can be formed on the metal layer 130. The protrusions 134 can be formed by stamping them towards the casing 140′ from the metal layer 130. A gap between the casing 140′ and the heat dissipation structure 200 can be formed due to the protrusions 134 abutting against the casing 140′. The positions of the protrusions 148 and the protrusions 134 can be determined according to heat dissipation requirements of the electronic device 100. It is noted that, the protrusions 148 and the protrusions 134 can also be applied in the second embodiment in FIG. 7. In this case, the protrusions can be formed on the inner side of the casing 140 or on the second electrically insulating and thermally conductive layer 170 or on the metal layer 130 such that a gap is disposed between the heat dissipation structure 202 and the casing 140.

Besides chemical bonding mentioned above, the combination of the first electrically insulating and thermally conductive layer 120 with the metal layer 130 in the heat dissipation structure may employ other chemical or physical methods such as superimposing or other adhesion promoters to make the first electrically insulating and thermally conductive layer 120 and the metal layer 130 in thermal contact with each other. The followings are the other exemplified embodiments of this disclosure.

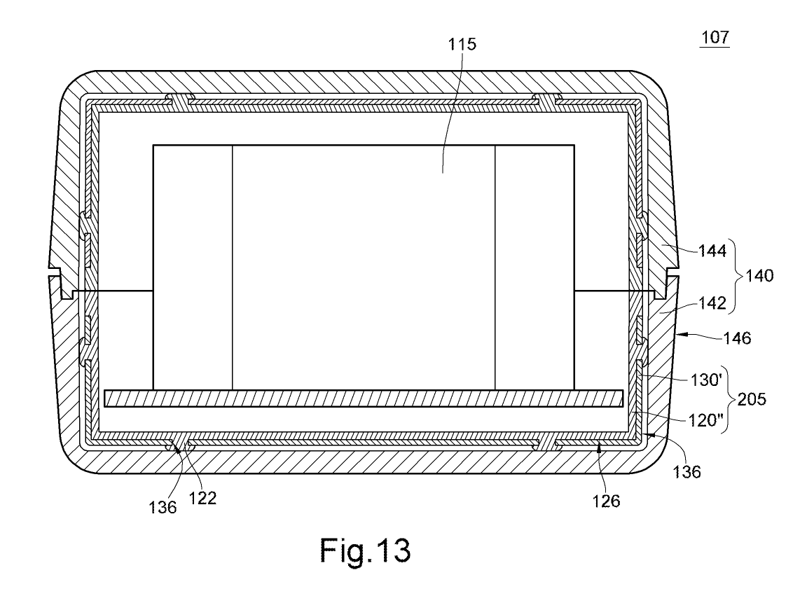

FIG. 13 is a cross-sectional view of an electronic device according to a fifth embodiment of the disclosure, which is explained with the element construction of the first embodiment. The first electrically insulating and thermally conductive layer 120″ in the electronic device 107 may comprise a coupling portion 122 which is protruded from the first electrically insulating and thermally conductive layer 120″ toward the casing 140. The coupling portion 122 is penetrated through a hole 136 on the metal layer 130′. The coupling portion 122 extends outside the hole 136 to form as a rivet so that the metal layer 130′ is combined and fixed to the first electrically insulating and thermally conductive layer 120″ and a one-piece heat dissipation structure 205 is thus formed. In the manufacturing of the heat dissipation structure 205, a metal plate is punched to form the hole 136. Then, an electrically insulating and thermally conductive sheet is placed on the metal plate. The metal plate and the electrically insulating and thermally conductive plate are heated and compressed by a mold so that a part of the electrically insulating and thermally conductive sheet is penetrated through the hole 136 to form the coupling portion 122 so as to combine the first electrically insulating and thermally conductive layer 120″ with the metal layer 130′.

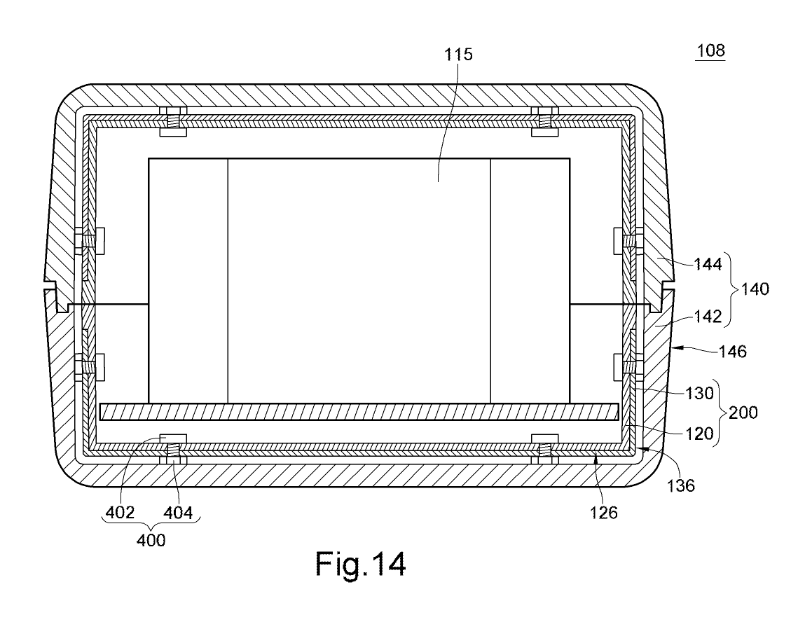

FIG. 14 is a cross-sectional view of an electronic device according to a sixth embodiment of the disclosure, which is explained with the element construction of the first embodiment. The first insulating and heat conduction layer 120 in the electronic device 108 can also be in thermal contact with the metal layer 130 through an electric insulating fastener 400, such as a plastic screw 402 and a plastic nut 404.

In addition, since the first or/and second electrically insulating and thermally conductive layer in the disclosure can be made of soft materials such as heat conductive rubber or heat conductive silicone, the first or/and second electrically insulating and thermally conductive layer can effectively absorb the structural variation such as warping or brittle fracturing which is caused by the different thermal expansion coefficients of the first or/and second electrically insulating and thermally conductive layer and the metal layer when the first or/and second electrically insulating and thermally conductive layer are combined with the metal layer. The same situation can also be applied to the structural variation caused by different thermal expansion coefficients of the electrically insulating and thermally conductive layers, the metal layer, and the casing. Therefore, the electronic device employing the heat dissipation structure disclosed herein can pass the thermal shock test. Furthermore, the first or/and the second electrically insulating and thermally conductive layer can effectively absorb the noise produced by the vibration of the electronic components in the electronic device. Thus, the electronic device employing the heat dissipation structure disclosed herein can pass the noise test.

According to the above-mentioned embodiments and other derived and varied embodiments, the heat dissipation structure of the disclosure can distribute uniformly the temperature on the surface of the casing and can effectively reduce the temperatures of the hot spots on the surface of the casing, compared with the conventional heat dissipation structure. Furthermore, the working procedures, the assembling hours, and the number of workers can be reduced effectively so as to reduce the cost and improve the yield rate. The insulation requirements for safety regulations and various mechanical tests can also be met. The heat dissipation structure of the disclosure can be flexibly designed according to the different heat dissipation requirements of the electronic device; that is, the designs for the casing and the heat dissipation structure can be cooperated in favor of reduction of the temperatures of the hot spots on the surface of the casing or the high temperatures of the electronic components in the electronic device.

Note that the specifications relating to the above embodiments should be construed as exemplary rather than as limitative of the present disclosure, with many variations and modifications being readily attainable by a person of average skill in the art without departing from the spirit or scope thereof as defined by the appended claims and their legal equivalents.

What is claimed is:

1. An electronic device, comprising:
a circuit board;
a plurality of electronic components electrically connected to the circuit board; and
a heat dissipation structure, comprising:
a first electrically insulating and thermally conductive layer, covering the circuit board and/or the plurality of electronic components and having a thermal conductivity coefficient of greater than 0.5 W/m.k; and
a metal layer, combining with and being thermal contact with the first electrically insulating and thermally conductive layer; and
a casing, having an accommodating space in which the circuit board, the plurality of electronic components and the heat dissipation structure are accommodated, and the metal layer being disposed between the casing and the first electrically insulating and thermally conductive layer.

2. The electronic device as claimed in claim 1, wherein the heat dissipation structure further comprises a first adhesion disposed between the first electrically insulating and thermally conductive layer and the metal layer, and the first adhesion is respectively chemically bonded with the first electrically insulating and thermally conductive layer and the metal layer.

3. The electronic device as claimed in claim 1, wherein the heat dissipation structure further comprises a second electrically insulating and thermally conductive layer which is in thermal contact with the metal layer and has a thermal conductivity coefficient of greater than 0.5 W/m.k, and the metal layer is disposed between the first and the second electrically insulating and thermally conductive layers.

4. The electronic device as claimed in claim 3, wherein the second electrically insulating and thermally conductive layer is chemically bonded with the metal layer, the second electrically insulating and thermally conductive layer, forms the heat dissipation structure as a whole together with the metal layer and the first electrically insulating and thermally conductive layer, and completely covers the metal layer together with the first electrically insulating and thermally conductive layer.

5. The electronic device as claimed in claim 4, wherein the heat dissipation structure further comprises a second adhesion disposed between the second electrically insulating and thermally conductive layer and the metal layer and respectively chemically bonded with the second electrically insulating and thermally conductive layer and the metal layer.

6. The electronic device as claimed in claim 5, wherein the heat dissipation structure further comprises a third adhesion disposed between the second electrically insulating and thermally conductive layer and the casing and respectively chemically bonded with the second electric insualting and heat conduction layer and the casing in order to have the heat dissipation structure fixed on the casing.

7. The electronic device as claimed in claim 6, wherein the heat dissipation structure further comprises a bump extended from the first electrically insulating and thermally conductive layer toward the accommodating space and in contact with one of the plurality of electronic components or the circuit board.

8. The electronic device as claimed in claim 2, wherein the heat dissipation structure further comprises a fourth adhesion disposed between the metal layer and the casing and respectively chemically bonded with the metal layer and the casing in order to have the heat dissipation structure fixed on the casing.

9. The electronic device as claimed in claim 1, wherein the first electrically insulating and thermally conductive layer further comprises a coupling portion, the metal layer further comprises a hole, and the coupling portion is penetrated through the hole to extend outside the hole in order to have the metal layer combined and fixed to the first electrically insulating and thermally conductive layer to form the heat dissipation structure as a whole.

10. The electronic device as claimed in claim 1, wherein the heat dissipation structure further comprises an insulating fastener for combining the first electrically insulating and thermally conductive layer and the metal layer to form the heat dissipation structure as a whole.

11. The electronic device as claimed in claim 1, wherein the electronic device is an adapter, the casing comprises an upper surface, a bottom surface, a left surface, a right surface, an electric power input side surface and an electric power output side surface opposite to the electric power input side surface, and the upper surface, the bottom surface, the left surface, the electric power input side surface, and the electric power output side surface are formed the accommodating space, the circuit board comprises a voltage input side and a voltage output side, the voltage input side is adjacent to the electric power input side surface, the voltage output side is adjacent to the electric power output side surface, the first electrically insulating and thermally conductive layer covers inner surfaces of the upper surface, the bottom surface, the left surface, the right surface, the power input side surface and the power output side surface, and the first electrically insulating and thermally conductive layer covers parts of the voltage input side and the voltage output side.

12. The electronic device as claimed in claim 1, wherein the casing further comprises a protrusion protruding toward and abutting against the heat dissipation structure such that a gap is formed between the casing and the heat dissipation structure.

13. The electronic device as claimed in claim 1, wherein the metal layer comprises a protrusion protruding from the metal layer toward and abutting against the casing, such that a gap is formed between the casing and the heat dissipation structure.

14. A heat dissipation structure, comprising:
a first electrically insulating and thermally conductive layer, having a thermal conductivity coefficient of greater than 0.5 W/m.k; and
a metal layer in thermal contact and chemically bonded with the first electrically insulating and thermally conductive layer.

15. The heat dissipation structure as claimed in claim 14, further comprising a first adhesion disposed between the first electrically insulating and thermally conductive layer and the metal layer and respectively chemically bonded with the first electrically insulating and thermally conductive layer and the metal layer.

16. The heat dissipation structure as claimed in claim 14, further comprising a second electrically insulating and thermally conductive layer with a thermal conductivity coefficient greater than 0.5 W/m.k, in thermal contact with and chemically bonded with the metal layer, and the metal layer being disposed between the first and the second insulation and heat conduction layers, the second electrically insulating and thermally conductive layer, the metal layer, and the first electric insulting and heat conduction layer forming the heat dissipation structure as a whole.

17. The heat dissipation structure as claimed in claim 16, wherein the second and the first electrically insulating and thermally conductive layers together cover the metal layer, the heat dissipation structure further comprises a second adhesion disposed between the second electric insulting and heat conduction layer and the metal layer and respectively chemically bonded with the second electrically insulating and thermally conductive layer and the metal layer.
